(19) United States
(12) Patent Application Publication
(10) Pub. No.: US 2018/0205375 A1
(43) Pub. Date: Jul. 19, 2018

(54) CIRCUIT ARRANGEMENT FOR A SECURE DIGITAL SWITCHED OUTPUT, TEST METHOD FOR AND OUTPUT MODULE FOR THE SAME

(71) Applicant: Weidmüller Interface GmbH & Co. KG, Detmold (DE)

(72) Inventor: Gorm ROSE, Paderborn (DE)

(21) Appl. No.: 15/736,391

(22) PCT Filed: Jun. 24, 2016
(86) PCT No.: PCT/EP2016/064724

§ 371 Date: Dec. 14, 2017

(30) Foreign Application Priority Data
Jun. 25, 2015 (DE) 20 2015 103 339.7

(51) Int. Cl. H03K 17/18; G01R 31/26

(52) U.S. Cl. CPC H03K 17/18; G01R 31/2617; G01R 31/2621

(57) ABSTRACT

A circuit for a digital switched output for connecting a load which can be connected between the switched output and another output includes at least one semiconductor switch arranged with a clearance between contacts between a supply voltage connection and the switched output. At least one semiconductor switch is connected to the switched output via an inductor wherein a connecting node between the semiconductor switch and the inductor is connected to the other output via a free-running element. An output module provides automated control of the circuit. A method for testing the circuit includes controlling the semiconductor switch for operation of the load, interrupting the controlling, operating the load with energy stored in the inductor, determining whether voltage is prevented from being supplied to the load, and further controlling the semiconductor switch for further operation of the load.

This application is a § 371 National Stage Entry of PCT/EP2016/064724 filed Jun. 24, 2016 entitled “Circuit Arrangement for a Secure Digital Switched Output, Test Method for—and Output Module Comprising a Digital Circuit Arrangement of this Type.” PCT/EP2016/064724 claims priority of DE 202015103339.7 filed Jun. 25, 2015. The entire contents of these applications are incorporated herein by reference in their entireties.

### BACKGROUND OF THE INVENTION

The invention relates to circuits. More particularly, it relates to a circuit for a secure digital switched output for connecting a load which can be connected between the switched output and another output.

The circuit is used, for example, in digital output modules of industrial automated controls. For many applications, particularly applications that are critical for security, it must be ensured in such output modules that a switched output is securely switched off, if required by the automated control or an additional security device. This applies particularly if an actuator is controlled via the switched output and if its operation can result in hazard for operators of an installation.

### BRIEF DESCRIPTION OF THE PRIOR ART

As disclosed in the European standard EN 13849-1, two series-connected semiconductor switches are commonly used in order to ensure that no supply voltage is applied at the switched output during the switch-off process as a result of the redundant design. In a series connection of this type, an interruption of the power supply, for example to an actuator, still occurs even if one of the two semiconductor switches is defective and has assumed a permanently conductive state.

The correct operation, in particular the correct switching off, of the circuit for the digital switched output is regularly verified by a test method.

For this purpose, it is possible to measure a voltage level at the digital switched output, while the switched output is switched off for the briefest possible operating time. Such a brief switching off is also referred to as “blanking.” If the brief blanking can also be observed at the switched output, this indicates a correct switching off capacity of at least one semiconductor switch. For many application purposes, such blanking, even if kept very brief, is not desirable during operation, since it interferes with the correct operation of the load controlled by the switched output.

EP 1 389 284 B1 discloses a circuit for a security switch module in which, parallel to a first current path in which at least one semiconductor switch is located, there is a second current path, which also has at least one semiconductor switch. During operation, voltage is applied alternately to the switched output via one or the other current paths, wherein the respective non-active current path is verified with regard to the function of the semiconductor switch thereof. In this manner, with the switched output on, it is possible to verify that the semiconductor switches are being used without the switched output being briefly blanked by the test output. However, this functionality leads to a doubling of the number of semiconductor switches and to a more complex verification circuit.

### SUMMARY OF THE INVENTION

An object of the present invention is to provide a circuit for a digital switched output and an output module which, with the smallest possible number of semiconductor switches used and without a brief blanking occurring at the switched output, verifies that the semiconductor switches are functioning. Another object is to describe a test method for a circuit of this type, which verifies the correct functioning of a semiconductor switch of the circuit without interrupting the supply load.

The circuit has a digital switched output for connecting a load between a switched output and a second output, including at least one semiconductor switch connected with a supply voltage, an inductor connected with the semiconductor switch and with the switched output, a connecting node between the semiconductor switch and the inductor, and a free-running element connected between the connecting node and the second output. The elements of the circuit provide for testing the circuit during operation without interrupting a voltage supplied to a load connected with the switched output.

In the circuit according to the invention, switching off the semiconductor switch does not lead to an immediate switching off of the load. Instead, the current flow through the dropping magnetic field of the inductor is maintained and continues to flow briefly via the inductor, the load and the free-running element. This can be used for verification of the correct switching off of the semiconductor switch. During a brief blanking pulse of the semiconductor switch during a test, the combination of an inductor and free-running element leads to continued maintenance of a current flow through the connected load. The verification can be completed without the blanking manifesting itself on the load.

The circuit preferably includes a control and test circuit which controls the semiconductor switch and determines whether there is a brief blanking pulse in the control of the semiconductor switch. Here, the test connection can be connected to the connecting node between the semiconductor circuit and the inductor. Alternatively, it is also possible to connect the test connection to the switched output. In this case, the control and test circuit are configured so as to determine a current flowing at the switched output from a voltage change determined at the switched output during a blanking pulse. A current measurement thus becomes possible without an additional current measuring device, for instance without shunt. The determined current value can also be monitored and it provides information regarding any problems present during the connection of the load, such as a line break.

In a preferred embodiment of the circuit, for the purpose of increasing the switching security, two or more semiconductors are connected in series.

In another embodiment of the circuit, a capacitor is arranged between the switched output and the other output parallel to the load. The capacitor supports the maintenance of the current flow at the output during a brief blanking and minimizes voltage changes at the output.

In a further embodiment of the circuit, the free-running element includes a diode or is a diode. Due to the potentials formed, the diode becomes conductive and securely closes the current circuit extending via the inductor and load during a blanking. Alternatively or additionally, a transistor is connected in parallel and used as the free-running element to be controlled synchronously with the blanking pulses. In the case of a low passage resistance of the transistor, energy losses that occur in the case of a diode as a free-running element and which can lead to heating the diode can be prevented.

In another embodiment of the circuit, the other output is also switched and connected via at least one additional semiconductor switch to another supply voltage connection so that separation can be carried out at all the poles.

According to another embodiment of the circuit, a reverse polarity protection switch is connected upstream of the semiconductor switch and/or one or more additional semiconductor switches.

An output module for automated control includes at least one digital switched output of a circuit for controlling the digital switched output.

A test method is also provided for a circuit that includes a digital switched output for connecting a load via an inductor and at least one semiconductor switch arranged between a supply voltage connection and a switched output. The test method includes the following steps: controlling the at least one semiconductor switch for operation of a load connected to a switched output, interrupting the controlling step, operating the load with energy stored in the inductor, determining whether the interrupting step prevents the supply of voltage to the load, and further controlling the at least one semiconductor switch for further operation of the load connected to the switched output. Because the inductor continues to supply the load during the determining step, the test method can be implemented without interrupting the load.

The steps of interruption of the control of the at least one semiconductor switch and of determining whether the at least one semiconductor switch prevents the supply of voltage to the load can be carried out repeatedly. The repetition can occur, for example, in a periodically recurring manner. In this manner, the correct functionality of the semiconductor switch, in particular the capacity thereof to separate the load from the supply voltage, is continuously ensured.

### BRIEF DESCRIPTION OF THE FIGURES

Other objects and advantages of the disclosure will become apparent from a study of the following specification when viewed in the light of the accompanying drawing, in which:

FIG. 1 is a circuit for a digital switched output according to a first embodiment;

FIG. 2 is a circuit for a digital switched output according to a second embodiment; and

FIG. 3 is a circuit for a digital switched output according to a third embodiment.

### DETAILED DESCRIPTION

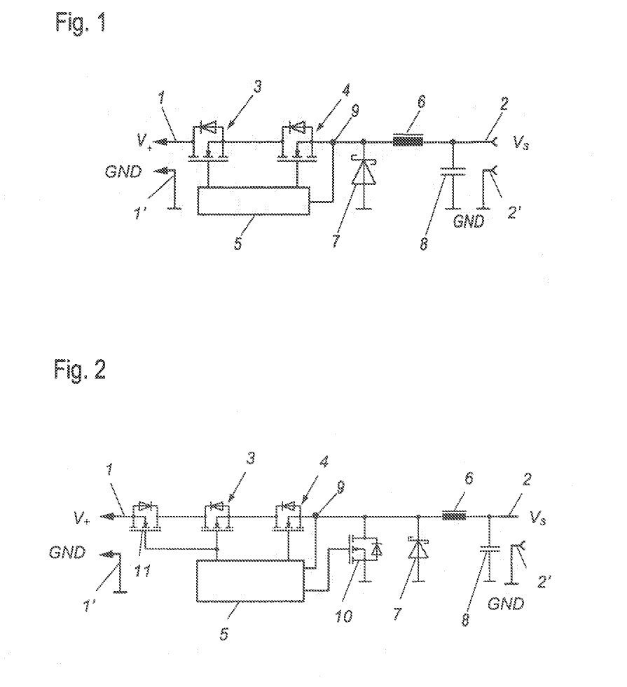

Referring first to FIG. 1, the circuit includes a supply voltage connection 1 to which a supply voltage V₊ is applied. The supply voltage V₊ relates to a reference voltage level which is formed by a ground potential GND. The ground potential is provided via a reference voltage or ground connection 1′. The supply voltage V₊ and the ground potential GND are provided by an external power supply (not shown).

The circuit is part of an output module which is used within an industrial automated installation. The circuit has a digital switched output 2 or is connected to the switched output, to which an output voltage Vₛ, which can be switched on or off, is applied by the circuit. The output voltage Vₛ again relates to the ground potential GND which is also provided at another output 2′ of the circuit. The circuit is used for the secure controlled switching on or off of a load connected between the switched output 2 and the other output 2′.

In this embodiment, two series-connected semiconductor switches 3, 4 are connected between the supply voltage connection 1 and the switched output 2. Metal oxide semiconductor field effect transistors (MOSFETs) are used as semiconductor switches. The semiconductor switches 3, 4 have an internal bypass diode. It is understood that instead of the MOSFETs, bipolar transistors or insulated gate bipolar transistors (IGBTs), for example, can also be used.

Two series-connected semiconductor switches 3, 4 are provided in order to increase the switching security, in particular the switch-off security.

The semiconductor switches 3, 4 are controlled via the control connection thereof (here the gate connection) by a control and test circuit 5. The control and test circuit 5 receives an input signal via an input (not shown) and switches the semiconductor switches 3, 4 on or off in accordance with the input signal.

Between the semiconductor switches 3, 4 and the switched output 2, an inductor 6 is connected and a diode 7 is connected as a switching device between the reference potential and the connecting nodes between the series connection of the semiconductor switches 3, 4 and the inductor. A capacitor 8 is connected between the outputs 2, 2′.

The circuit shown in FIG. 1 is used for the controlled switching on and off of a load connected to the switched output 2 or to the other output 2′. To verify that the semiconductor switches 3, 4 are functioning correctly in the switched on state, the control and test circuit 5 is configured to switch the semiconductor switches 3, 4 off and then on again to briefly blank, independently of one another, such as alternately one after the other with intermediate pauses. At the output of the series connection of the semiconductor switches 3, 4, i.e. at the connecting node to the inductor 6, a test connection 9 is arranged, the potential of which is measured and verified by the control and test circuit 5. The test connection 9 indicates whether a blanking of the control connections, i.e. the gate connections of the semiconductor switches 3, 4, has also successively led to the interruption of the clearance between contacts of the semiconductor switches 3, 4.

The blanking of one of the semiconductor switches 3, 4 leads to an interruption of the current flow between the series connection of the semiconductor switches 3, 4 and of the inductor 6. According to Lenz's law, the current flow is maintained by the dropping magnetic field of the inductor 6, as a result of which the diode 7 becomes conductive. During the brief blanking pulse, the combination of the inductor 6 and diode 7 maintains the flow of the connected load. The resulting circuit current extends via the diode 7, the inductor 6 and the load connected to the switched output 2 or to the other output 2′.

The capacitor 8, which is optionally arranged parallel to the load, supports this behavior and maintains the supply voltage V₊ with respect to the ground potential GND. The inductance value of the inductor 6, preferably formed by a coil with a ferrite core, is dimensioned so that for the duration of the blanking pulse, the voltage at the switched output 2 is maintained to the extent possible with only a small voltage drop. Preferably, the blanking times are in the range from several i.e 10 microseconds (μs) to less than 1 μs is in order to deliver even stronger currents in the range from several amps (A) through the inductor 6 for a sufficiently long time without the inductor 6 requiring an excessively high inductance value. A maximum voltage drop of approximately 5%-7% can be tolerated during the blanking time for usually connected loads. For example, a supply voltage V₊ of 24 volt (V), a 1.5 V drop, can generally be tolerated. By adapting the size of the inductance value of the inductor 6, an even smaller voltage drop can be carried out, if necessary.

While the output voltage Vₛ is substantially maintained in this manner at the switched output 2 during the blanking pulse, when the semiconductor switches 3, 4 are working correctly, the output voltage decreases at the test connection 9 to a voltage which corresponds to the breakdown voltage of the diode 7. This lowering of the supply voltage V₊ to the forward voltage of the diode which is negative with respect to the ground potential at the test connection 9 and typically less than one volt, is detected by the control and test circuit 5 and evaluated as a sign of a correctly switched-off semiconductor switch 3, 4. If the voltage at the test connection 9 does not decrease, this is a sign of a defective semiconductor switch 3 and/or 4, or a sign that no load is connected to the output. The latter can also be interpreted as a potential error since it can be caused by a cable break or other issue.

In an alternative design of the circuit, the switched output 2 is used as a test connection. In this design, no lowering to the low voltage value of the breakdown voltage of the diode 7 is detected by the control and test circuit 5, but only a slight lowering is detected because the inductor 6 and the capacitor 8 exhibit an exponential discharge behavior. Even if the inductor 6 and diode 7, and optionally the capacitor 8, are suitable for maintaining the output voltage Vₛ at the switched output such that an included load can be passed on without a problem, a detectable lowering of the voltage Vₛ at the switched output 2 occurs nevertheless.

When measuring the voltage at the capacitor 8, the value of the current flowing at the output or whether any current flows at all at the output can be noted. The determined current value or current flow can also be monitored to, among other things, provide information regarding any problems during the connection of the load, such as a line break.

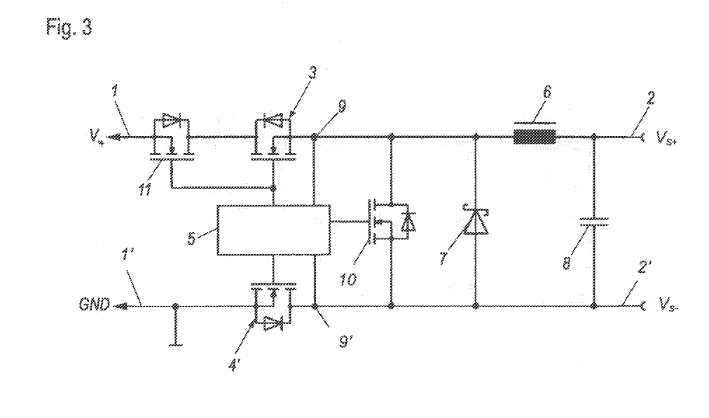

FIG. 2 is a diagrammatic circuit diagram a second embodiment of a circuit for a digital switched output. In this figure as well as in the following FIG. 3, identical reference numerals mark identical or equivalent elements as those of FIG. 1.

In the basic design, the circuit represented in FIG. 2 corresponds to the circuit represented in FIG. 1.

In contrast to the embodiment example of FIG. 1, a transistor 10, such as a MOSFET, is arranged parallel to the diode 7. In the embodiment of FIG. 1, the diode 7 represents an uncontrolled free-running element which becomes conductive during a blanking of one of the semiconductor switches 3, 4 due to the potentials formed at the connections thereof.

The transistor 10 thus also represents a free-running element having the same function as the diode 7. For this purpose, it is controlled by the control and test circuit 5 synchronously with the blanking pulses. The passage resistance of the transistor 10 is so low that in the conductive state, there is only a slight, negligible voltage drop across the transistor 10. Accordingly, energy losses that occur in the circuit of FIG. 1 at the diode 7 and that can lead to heating of the diode 7 are avoided. Small energy losses also lead to the load connected to the switched output 2 being supplied for a longer time by the energy stored in the inductor 6 or in the capacitor 8. In the case of a predetermined length of the blanking pulses, the inductor 6 and the capacitor 8 can thus be dimensioned with lower inductance or capacity values.

Another difference from the embodiment of FIG. 1 is the series connection of the polarity protection switches 11 connected upstream of the semiconductor switches 3, 4. This polarity protection switch could be formed passively by a diode; however, in this case, a MOSFET transistor is used for decreasing voltage drops.

FIG. 3 shows another embodiment of a circuit according to the invention for a digital switched output. In this embodiment, the output is switched at all of the poles.

There are supply voltage connections 1, 1′ for a positive voltage supply V₊ and a ground potential GND, respectively. Each of these supply voltage connections 1, 1′ is connected via a respective semiconductor switch 3 or 4′ to the output of the circuit. Accordingly, the two poles of the output are connected and marked in FIG. 3 as switched output 2 or additional switched output 2′ with corresponding output voltages Vₛ₊ or Vₛ₋.

A control and test circuit 5 controls the two semiconductor switches 3, 4′. The voltage applied between two test connections 9, 9′ is determined during a blanking pulse.

A polarity protection 11 is connected downstream of the positive supply voltage connection 1.

The circuit including inductor 6, diode 7 and capacitor 8, which enables the supply of the load connected to the switched output 2, 2′ in the blanking pulses of the control and test circuit 5, is designed similarly to those of FIGS. 1 and 2, wherein the inductor 6 is connected upstream of the switched output 2, and wherein, via the diode 7, the node between the semiconductor circuit 3 and a connection of the inductor 6, is connected to the other switched output 2′. The capacitor is connected parallel to the switched outputs 2, 2′.

A transistor 10 is connected parallel to the diode 7 and controlled during the blanking pulse by the control and test circuit 5 and used in addition to the diode 7 as a free-running element.

During switching off of the switched output 2, 2′, a separation from the supply voltage V₊ or GND is carried out at all of the poles. The advantage of the separation at all the poles is that an external short circuit of a line which leads away from the switched output 2 and which permanently applies the supply voltage V₊ to the load does not represent a security loss since the line leading away from the other switched output 2′ is also switched off.

1-15. (canceled)

16. A circuit having a digital switched output for connecting a load between the switched output and a second output, comprising:
(a) at least one semiconductor switch connected with a supply voltage;
(b) an inductor connected with said semiconductor switch and with said switched output;
(c) a connecting node between said semiconductor switch and said inductor; and
(d) a free-running element connected between said connecting node and said second output, whereby the circuit may be tested during operation without interrupting a voltage supplied to a load connected with said switched output.

17. A circuit arrangement as defined in claim 16, further comprising a capacitor connected between said switched output and said second output.

18. A circuit arrangement as defined in claim 16, wherein said free-running element comprises a diode.

19. A circuit arrangement as defined in any one of claim 16, wherein said free-running element comprises a transistor.

20. A circuit arrangement as defined in claim 19, wherein said transistor is connected with said connecting node.

21. A circuit arrangement as defined in claim 20, wherein said transistor is connected in parallel with said diode.

22. A circuit arrangement as defined in claim 16, wherein said second output is a ground connection.

23. A circuit arrangement as defined in claim 16, and further comprising at least one additional semiconductor switch and an additional supply voltage connection, said additional semiconductor switch being connected between said additional supply voltage connection and said second output.

24. A circuit arrangement as defined in claim 16, and further comprising a polarity protection switch connected upstream of said at least one semiconductor switch.

25. A circuit arrangement as defined in claim 16, and further comprising
(a) a control and test circuit connected with said at least on semiconductor switch; and
(b) a test connection, wherein said control and test circuit controls said at least one semiconductor switch and determines whether a brief blanking pulse is observable at said test connection.

26. A circuit arrangement as defined in claim 25, wherein said test connection is connected with said connecting node.

27. A circuit arrangement as defined in claim 26, wherein said test connection is connected with said switched output.

28. A circuit arrangement as defined in claim 27, wherein said control and test circuit determines a current flowing at said switched output during a blanking pulse.

29. An output module for automated control, comprises at least one digital switched output of a circuit as defined in claim 16 for controlling said at least one digital switched output.

30. A test method for a circuit including a digital switched output for connecting a load via an inductor, wherein the circuit includes at least one semiconductor switch arranged between a supply voltage connection and a switched output, comprising the steps of:
(a) controlling the at least one semiconductor switch for operation of a load connected to a switched output;
(b) interrupting said controlling step;
(c) operating said load with energy stored in the inductor,
(d) determining whether said interrupting step prevents voltage from being supplied to the load; and
(e) further controlling the at least one semiconductor switch for further operation of the load connected to said switched output.

31. A method as defined in claim 30, in which said interrupting step and said determining step are carried out repeatedly.
